(19) United States
(12) Patent Application Publication
(10) Pub. No.: US 2009/0219065 A1
(43) Pub. Date: Sep. 3, 2009

(54) Semiconductor Device and Electronic Apparatus

(75) Inventor: Akira Shimizu, Kyoto (JP)

Correspondence Address: FISH & RICHARDSON, P.C.;Citigroup Center, 153 East 53rd Street, 52nd Floor, New York, NY, 10022-4611, US

(73) Assignee: ROHM CO., LTD., Kyoto (JP)

(21) Appl. No.: 11/720,910

(22) PCT Filed: Dec. 21, 2005
(86) PCT No.: PCT/JP2005/023473

§ 371 Date: Jun. 5, 2007

(30) Foreign Application Priority Data
Dec. 28, 2004 (JP) 2004-380493

(51) Int. Cl. H03L 7/00

(52) U.S. Cl. 327/143; 327/141

(57) ABSTRACT

A read-start-timing set circuit is connected to a timing terminal (CT1) of a semiconductor device. By comparing an internal signal of this semiconductor device with an external signal on a bus line, the read timing immediately after power is turned on is modified. Since data transmission onto the bus line from another semiconductor device is inhibited, adjustment is effected to avoid data collision between the semiconductor devices. Therefore, automatic reading after power is turned on can be conducted while avoiding data collision between the semiconductor devices on the bus line to which a plurality of semiconductor devices are connected. Furthermore, a relevant semiconductor device can be readily attached onto the bus line.

### TECHNICAL FIELD

The present invention relates to a semiconductor device for data transfer, and an electronic apparatus including such a semiconductor device. The present invention particularly relates to a semiconductor device configured to avoid data collision on a bus line in an operation mode following power-on at a bus line system having a plurality of ICs (Integrated Circuits) connected via a bus line, each IC transmitting/receiving data to/from another desirable IC through a common communication procedure, and an electronic apparatus including the semiconductor device.

### BACKGROUND ART

For the purpose of providing display on one screen in accordance with increase in the size of the screen, a video apparatus is often configured using a plurality of ICs having the same capability and a microcomputer or the like for controlling these ICs. The microcomputer can effect data transfer with another IC via a bus line (for example, a serial bus line such as an I square C bus (I²C bus)). In a conventional bus system, many functional ICs and a microcomputer that controls data transfer are connected to one bus line.

Therefore, when data is to be transferred between the microcomputer and a functional IC or between functional ICs on one bus line, data collision must be avoided. A conventional method of preventing data collision includes the method of transmitting/receiving data based on time-divisional control of the bus line.

A method of adjusting data transmission/reception is disclosed in, for example, Japanese Patent Laying-Open No. 08-084154 (Patent Document 1). In this method, a switch control circuit incorporated in a microcomputer recognizes the data transfer destination. Information related to the data transfer destination is transferred to the microcomputer. The switch control circuit turns on the switch connected to the data transfer destination among the switches on the bus line, and turns off the remaining switches. Accordingly, data will not be transferred erroneously to an IC that is not used. However, this method is disadvantageous in that the microcomputer program to turn on/off a switch must be modified every time the screen size of the final product is changed. Further, the design of the circuit board on which the functional IC is mounted must be modified to accommodate increase in the number of corresponding ICs. These modifications may become a bottleneck in the development of the design procedure for the final product.

Patent Document 1: Japanese Patent Laying-Open No. 08-084154

### DISCLOSURE OF THE INVENTION

### Subject to be Solved by the Invention

An object of the present invention is to allow a bus system that does not require a microcomputer to administer collectively which functional IC the data on a bus line is to be transmitted/received, configurable by just a simple modification of the design of each functional IC.

### Means for Solving the Subject

A semiconductor device of the present invention includes a terminal for reading data from another semiconductor device, and a read-start-timing set circuit setting the timing to start reading of the data after power supply voltage is applied.

Preferably, the semiconductor device further includes a comparator circuit. The comparator circuit compares an internal signal that is output from the semiconductor device to an external source, and an external signal input from an outer source of the semiconductor device. The semiconductor device puts data reading on standby when the value of the internal signal differs from the value of the external signal.

Further preferably, the read-start-timing set circuit sets the timing to start data reading according to an input from the comparator circuit and an input from an external set terminal unit. The semiconductor device executes data reading when the value of internal signal matches the value of the external signal, and puts data reading on standby when the value of the internal signal differs from the value of the external signal. The semiconductor device generates a signal to set the timing to start reading at an elapse of a predetermined time from starting standby of data reading, and transmits the signal to the read-start-timing set circuit.

Preferably, the external set terminal unit includes a plurality of timing set terminals to set the timing to start data reading at the semiconductor device. The read-start-timing set circuit sets the timing to start reading according to each setting of the plurality of timing set terminals.

Preferably, the external set terminal unit is a voltage input terminal to set the timing to start reading at the semiconductor device. The read-start-timing set circuit sets the timing to start reading according to the voltage of the voltage input terminal.

Preferably, the external set terminal unit is connected to a capacitor or a resistor. The read-start-timing set circuit sets the timing to start reading according to a capacitance value of the capacitor or resistance value of the resistor.

Preferably, the external set terminal unit is a timing terminal to set the timing of a reset signal that resets the operation of the semiconductor device. The read-start-timing set circuit sets the timing to start reading by setting the timing of the reset signal according to the setting of the timing terminal.

More preferably, the external set terminal unit is a voltage input terminal to set the timing of a reset signal resetting an operation of the semiconductor device. The read-start-timing set circuit sets the timing to start data reading by setting the timing of the reset signal according to the voltage setting at the voltage input terminal.

More preferably, the external set terminal unit includes a plurality of terminals. The plurality of terminals is connectable to at least one of a capacitor and a resistor to set the timing of the reset signal resetting the operation of the semiconductor device. The read-start-timing set circuit sets the timing of a reset signal by modifying a capacitance value of the capacitor or a resistance value of the resistor connected to at least one of the plurality of terminals, and sets the timing to start data reading according to the timing of the reset signal.

According to another aspect of the present invention, a semiconductor device reading data automatically from another semiconductor device includes a comparator circuit and a read-start-timing set circuit. The comparator circuit compares the internal signal generated in the semiconductor device with an external signal applied from an external source of the semiconductor device. The read-start-timing set circuit sets the timing to start data reading according to an input from the comparator circuit and an input from an external set terminal unit. The comparator circuit generates a read failure signal when the value of the internal signal differs from the value of the external signal. The read-start-timing set circuit generates a signal to set again the timing to start reading when a read failure signal is received.

Preferably, the external set terminal unit includes a plurality of timing set terminals to set the timing to start data reading at the semiconductor device. The read-start-timing set circuit sets the timing to start reading according to each setting of the plurality of timing set terminals.

Preferably, the external set terminal unit is a voltage input terminal to set the timing to start reading at the semiconductor device. The read-start-timing set circuit sets the timing to start reading according to the voltage of the voltage input terminal.

Preferably, the external set terminal unit is connected to a capacitor or a resistor. The read-start-timing set circuit sets the timing to start reading according to a capacitance value of the capacitor or a resistance value of the resistor.

Preferably, the external set terminal unit is a timing terminal to set the timing of a reset signal that resets an operation of the semiconductor device. The read-start-timing set circuit sets the timing to start reading by setting the timing of the reset signal according to the setting of the timing terminal.

More preferably, the external set terminal unit is a voltage input terminal to set the timing of a reset signal resetting an operation of the semiconductor device. The read-start-timing set circuit sets the timing to start data reading by setting the timing of the reset signal according to the voltage setting at the voltage input terminal.

More preferably, the external set terminal unit includes a plurality of terminals. The plurality of terminals is connectable to at least one of a capacitor and a resistor to set the timing of a reset signal resetting an operation of the semiconductor device. The read-start-timing set circuit sets the timing of the reset signal by modifying a capacitance value of the capacitor or a resistance value of the resistor connected to at least one of the plurality of terminals, and sets the timing to start data reading according to the timing of the reset signal.

According to a further aspect of the present invention, an electronic apparatus includes a signal processing circuit, and a control circuit controlling the signal processing circuit. The control circuit includes a plurality of semiconductor devices. At least one of the plurality of semiconductor devices includes a communication terminal to effect communication with another semiconductor device, and a read-timing set circuit. The read-timing set circuit sets the read timing of data automatically read in from a storage element via the communication terminal after power is turned on. At least one of the plurality of semiconductor devices has a read timing different from the read timing of another semiconductor device.

Preferably, the signal processing circuit is a video display circuit.

### EFFECTS OF THE INVENTION

Since data from another semiconductor device can be sequentially read in automatically after power is turned on according to the semiconductor device of the present invention, the microcomputer no longer has to control the bus line after power is turned on. Further, according to the semiconductor device and electronic apparatus of the present invention, the read start time can be adjusted by an externally provided element of the semiconductor device. Therefore, the designer can readily accommodate the case where design modification of a semiconductor device is required to reflect increase of the screen size of a video display device.

### BRIEF DESCRIPTION OF THE DRAWINGS

FIG. 1 shows a configuration of a bus line system according to an embodiment in which a semiconductor device of the present invention is applied.

FIG. 2 represents in detail the interface of each of a semiconductor device 1 and semiconductor devices 2a and 2b.

FIG. 3 represents signals transferred between semiconductor device 1 and semiconductor device 2a, and between semiconductor device 1 and semiconductor device 2b.

FIG. 4 is a diagram to describe in detail the interface of each of semiconductor device 1 and semiconductor devices 2a and 2b according to a second embodiment of the present invention.

FIG. 5 represents a specific example of a circuit to set the timing.

FIG. 6 represents a manner of a reset signal generation circuit of the present invention.

FIG. 7 shows an example of a timing adjustment circuit employing a plurality of terminals.

FIG. 8 represents another example of a timing adjustment circuit employing a plurality of terminals.

### DESCRIPTION OF THE REFERENCE CHARACTERS

1, 2a, 2b semiconductor device, 3 bus line

### BEST MODES FOR CARRYING OUT THE INVENTION

As will be described hereinafter, each of a plurality of semiconductor devices can automatically read in data through a bus line to which the plurality of semiconductor devices are connected without data collision on the bus line after power is turned on. Further, the plurality of semiconductor devices can be readily attached on a bus line.

### First Embodiment

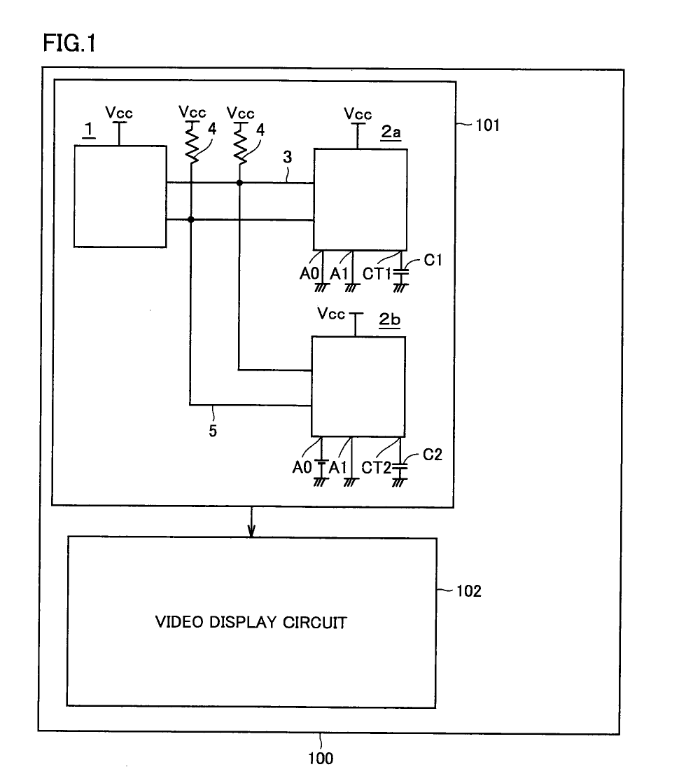

FIG. 1 shows a configuration of a bus line system according to an embodiment in which a semiconductor device of the present invention is applied. The bus line system is provided, for example, in a control circuit 101 that is incorporated in a video display device 100. Control circuit 101 is a video adjustment circuit adjusting the luminance and the like of the picture displayed at video display circuit 102. As an example of “signal processing circuit” of the present invention, a video display circuit 102 such as of a liquid crystal display device, plasma display device, or the like is shown in FIG. 1. The present invention is not limited to the embodiment of FIG. 1, and is applicable to the case where a control circuit includes a bus line system in an electronic apparatus including a signal processing circuit, and a control circuit that controls the signal processing circuit.

Semiconductor devices 2a and 2b are provided with timing set terminals CT1 and CT2, respectively. Timing set terminals CT1 and CT2 are connected to read-start-timing set circuits 25a and 25b provided in semiconductor devices 2a and 2b, respectively. Read-start-timing set circuits 25a and 25b set the timing to start reading of data from bus line 3. For example, capacitors C1 and C2 are connected to timing set terminals CT1 and CT2, respectively. Terminals A0 and A1 are address set terminals provided to generate an address signal of a relevant semiconductor device. A different address is set for each semiconductor device. Semiconductor device 1 is “another semiconductor device” that transmits data to semiconductor devices 2a and 2b. An E²PROM (Electrically Erasable/Programmable Read Only Memory) that is a non-volatile memory, for example, can be used for semiconductor device 1. A bus line 3 is the data line to connect relevant semiconductor devices together. A power supply voltage Vcc is coupled to bus line 3 via a pull-up resistor 4. A clock line 5 is a line through which is transmitted a clock signal that becomes the base of the input/output timing of ICs with each other. Pull-up resistor 4 is connected to clock line 5.

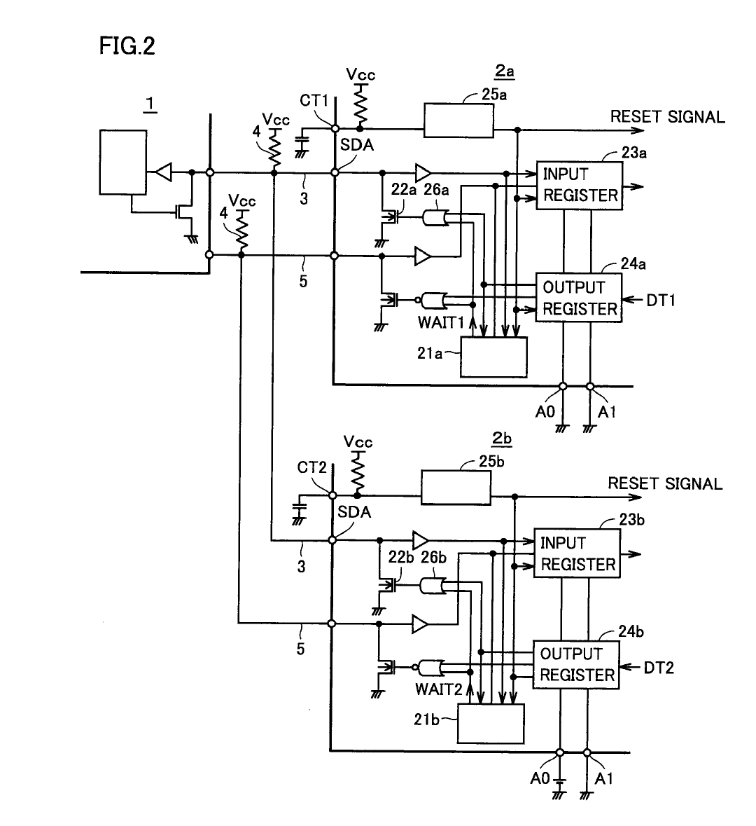

FIG. 2 represents in detail the interface of each of semiconductor device 1 and semiconductor devices 2a and 2b. Elements similar to those of FIG. 1 have the same reference characters allotted, and description thereof will not be repeated. Inside of semiconductor devices 2a and 2b are provided input registers 23a and 23b, output registers 24a and 24b, and internal and external data comparator circuit 21a and 21b, respectively. Each of input registers 23a and 23b retains external data SDA input through bus line 3. Output registers 24a and 24b retain internal data DT 1 and DT2, respectively. Each of internal and external data comparator circuits 21a and 21b compares the data retained in the input register with the data retained in the output register. To output registers 24a and 24b are connected, in addition to bus line 3 set forth above, the output terminals of read-start-timing set circuits 25a and 25b as well as terminals A0 and A1 for setting address data. Internal and external data comparator circuits 21a and 21b receive data output from output registers 24a and 24b, respectively, and data that are to be applied to input registers 23a and 23b, respectively. Internal and external data comparator circuits 21a and 21b also receive outputs of read-start-timing set circuits 25a and 25b, respectively, in addition to the data set forth above. Standby signals WAIT1 and WAIT2 are output from internal and external data comparator circuits 21a and 21b, respectively. Standby signals WAIT and WAIT2 are transmitted to logic circuits 26a and 26b, respectively, connected to the control electrodes of MOS transistors 22a and 22b. Each of MOS transistors 22a and 22b is provided to output data onto bus line 3. Each of MOS transistors 22a and 22b has its output terminal connected to bus line 3.

Semiconductor device 2a and semiconductor device 2b differ in the value of the capacitor connected to terminal CT1 and the value of the capacitor connected to terminal CT2. Further, semiconductor device 2a and semiconductor device 2b differ in the potential setting at address terminals A0 and A1. The value of the capacitor connected to terminal CT2 is larger than the value of the capacitor connected to terminal CT1.

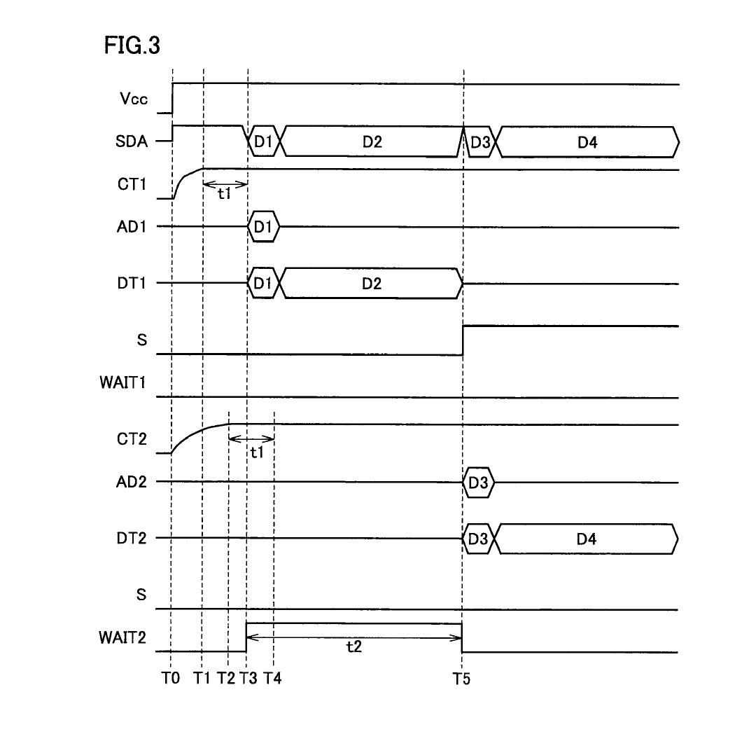

FIG. 3 represents the signals transmitted between semiconductor device 1 and semiconductor device 2a, and between semiconductor device 1 and semiconductor device 2b. Signal S in FIG. 3 relates to the second embodiment that will be described afterwards. An operation of semiconductor devices 2a and 2b will be described based on FIGS. 2 and 3. At time T0, power supply voltage Vcc rises. At time T1, a reset signal CT1 applied to timing terminal CT1 reaches a predetermined voltage. In response, the reset operation is canceled at semiconductor device 2a. Semiconductor device 2a transmits output data D1 to semiconductor device 1 via external signal terminal SDA and bus line 3 at time T2 corresponding to an elapse of a predetermined period t1 from a change in the potential of reset signal CT1. Output data D1 is based on address data AD1 according to the potential setting at terminals A0 and A1. Then, semiconductor device 1 receives output data D1, reads out data D2 specified by address data AD1 in output data D1, and transmits data D2 onto bus line 3. Semiconductor device 2a automatically reads in data D2 transmitted from semiconductor device 1, and effects internal setting as well as other signal processing based on data D2.

Semiconductor device 2b is adjusted such that the time of reset signal CT2 to reach a predetermined voltage is later than time T1. Therefore, the value of internal data DT2 does not match the value of external data SDA at time T3 that is before the read start time T4 of data D2 at semiconductor device 2a. Therefore, internal and external data comparator circuit 21b of semiconductor device 2b drives standby signal WAIT2 from a low level to a high level. During the period of a high-level standby signal WAIT2 being output (the period during which automatic read in of data D2 is effected at semiconductor device 2a), data can not be read in automatically at semiconductor device 2b. During this period, semiconductor device 2b does not transmit data onto bus line 3. The period during which standby signal WAIT2 of a high level is output corresponds to “predetermined time” in the present invention.

At time T5, an automatic read period t2 ends at semiconductor device 2a. Accordingly, standby signal WAIT2 is pulled down to a low level since external data SDA matches internal data DT2 of semiconductor device 2b. At this stage, the voltage of reset signal CT2 has arrived at the level of predetermined voltage. Semiconductor device 2b transmits address data AD2 (data D3) according to the potential setting at address terminals A0 and A1 to semiconductor device 1.

Semiconductor device 1 outputs data D3 subsequent to data D2. Semiconductor device 2b generates output data D3 according to the potential setting at address terminals A0 and A1 at time T5. Semiconductor device 2b automatically receives data D3. Since the value of external data SDA matches the value of internal data DT2 at internal and external data comparator circuit 21b, semiconductor device 2b transmits address data AD2 (data D3) to semiconductor device 1.

Semiconductor device 1 receiving address data AD2 reads out data D4 specified by address data AD2 and transmits the same to bus line 3. Semiconductor device 2b receives data D4. Semiconductor device 2b automatically reads in the data transmitted from semiconductor device 1 to carry out internal setting and other signal processing based on data D4 that has been read in. The switching of standby signal WAIT to a low level and high level may be modified appropriately. Specifically, standby signal WAIT2 may be set to switch from a high level to a low level at time t3.

### Second Embodiment

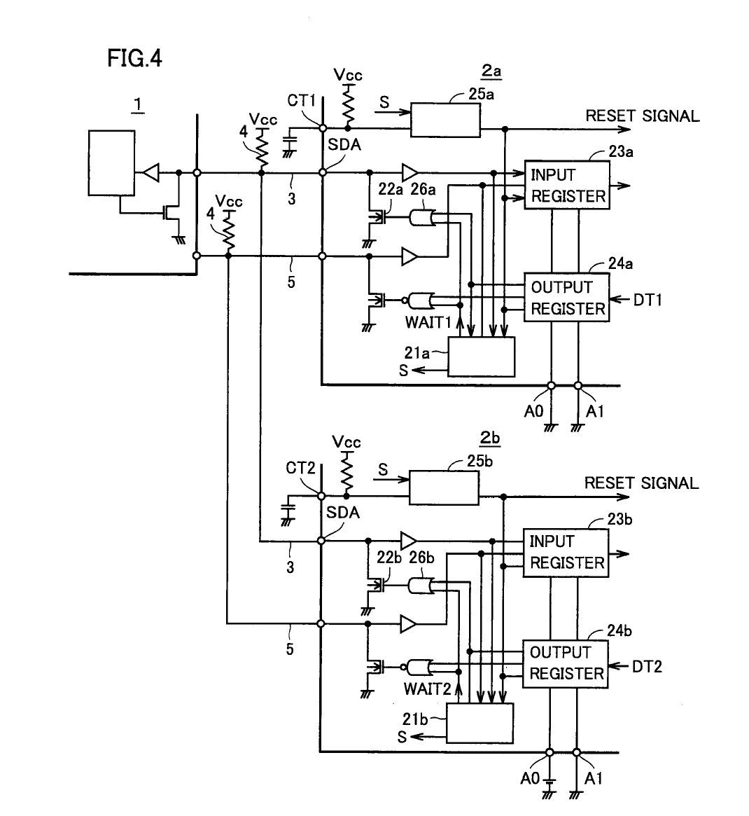

A configuration of the second embodiment is shown in FIG. 4. Similar configurations shown in FIGS. 1 and 2 have the same reference characters allotted, and description thereof will not be repeated. In the second embodiment, a semiconductor device having the data to be received defined is prevented from being reset as long as supply of power supply voltage Vcc is not cut. Therefore, in the present embodiment, the internal and external data comparator circuit alters standby signal WAIT and outputs a read-in define signal S at the semiconductor device having the data to be received defined. Read-in define signal S serves to cause a read-start-timing set circuit to generate a reset signal again at a semiconductor device where data transmission/reception is not conducted. The second embodiment differs from the first embodiment in that such an internal and external data comparator circuit and read-start-timing circuit are provided in each of semiconductor devices 2a and 2b. Following generation of a reset signal, an operation similar to that shown in FIG. 3 is repeated at each of semiconductor devices 2a and 2b. Specifically, one of the two semiconductor devices 2a and 2b alters standby signal WAIT and causes generation of a reset signal, when data reading is not effected at the other semiconductor device, to shift the timing to start data reading for the purpose of avoiding data collision at bus line 3. Accordingly, each semiconductor device can conduct a similar operation in the second embodiment even in the case where there are more than two semiconductor devices 2.

Standby signals WAIT1 and WAIT2 may be used for the generation of a reset signal instead of read-in define signal S. In this case, semiconductor devices 2a and 2b operate to alter standby signals WAIT1 and WAIT2, respectively, and cause read-start-timing set circuits 25a and 25b to generate a reset signal in response to standby signals WAIT1 and WAIT2, respectively. Following generation of a reset signal, an operation similar to the operation shown in FIG. 3 is repeated at the plurality of semiconductor devices 2. In other words, a semiconductor device of the present invention alters standby signal WAIT for reset, unless data reading succeeds, and shifts the timing to start reading. Thus, data collision can be avoided at bus line 3.

Standby signal WAIT in this case corresponds to “read failure signal” of the present invention.

A specific example of a circuit to set the timing is shown in FIG. 5. As shown in FIG. 5, a read-start-timing set circuit 25 and a set circuit 30 can be employed as the timing set circuit. Set circuit 30 is formed of a combination of a resistor and a capacitor. The timing to start reading can be readily adjusted by modifying the resistance and capacitance. At read-start-timing set circuit 25 is provided a Schmitt trigger type logic gate 250 with a threshold value in the transition from an L (low) level to an H (high) level differing from the threshold value in the transition from an H level to an L level for the reset signal line. Accordingly, an erroneous operation caused by noise or the like can be prevented.

Further, a power monitor circuit 251 and an NPN transistor 252 are provided at read-start-timing set circuit 25. For example, power supply voltage monitor circuit 251 senses reduction of power supply voltage Vcc to set NPN transistor 252 on. Accordingly, the level of the reset signal output from logic gate 250 changes. In accordance with the configuration shown in FIG. 5, a reset signal can be generated according to the state of the power supply voltage. Therefore, a reset cancel operation can be conducted in good timing according to the rise of the power of the electronic apparatus.

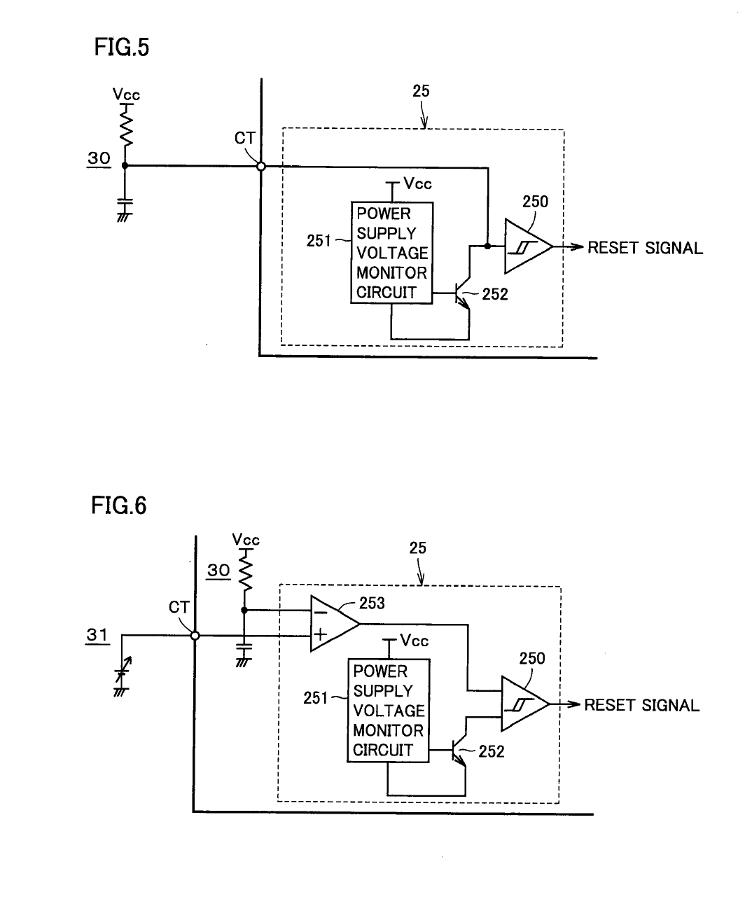

Another manner of a reset signal generation circuit connected to terminal CT is shown in FIG. 6. Set circuit 30 is provided in semiconductor device 2. A variable voltage source 31 is provided outside semiconductor device 2. By modifying the voltage value of variable voltage source 31, the threshold voltage of comparator circuit 253 is adjusted to set the timing to start reading. Terminal CT corresponds to “voltage input terminal” of the present invention.

The timing adjustment circuit may adjust the timing to start reading in accordance with a combination of the input voltage of each of a plurality of terminals. In this case, the timing adjustment circuit may be incorporated in a semiconductor device of the present invention, or provided outside the semiconductor device of the present invention.

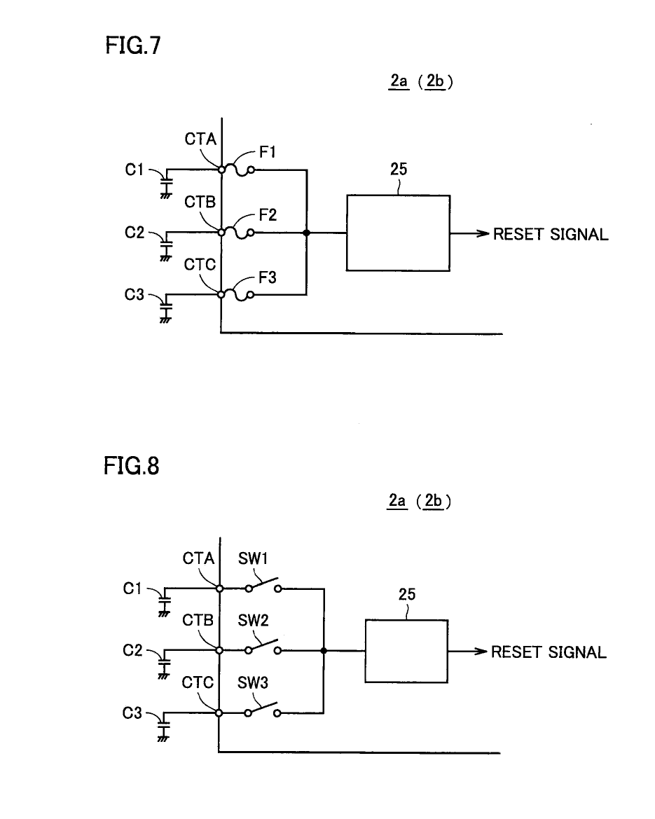

FIG. 7 shows an example of a timing adjustment circuit employing a plurality of terminals. Each of semiconductor devices 2a and 2b includes terminals CTA, CTB and CTC, qualified as external set terminals. Capacitors C1-C3 are connected to terminals CTA, CTB and CTC, respectively. Further, fuses F1-F3 are provided in semiconductor device 2 corresponding to terminals CTA, CTB and CTC, respectively. An input terminal of read-start-timing set circuit 25 is connected in common to each one terminal of fuses F1-F3. Since the time for reset signal CT1 (CT2) to arrive to a high level can be altered by modifying the capacitance through laser trimming, the timing to start reading can be adjusted.

FIG. 8 shows another example of a timing adjustment circuit employing a plurality of terminals. The configuration of FIG. 8 differs from the configuration of FIG. 7 in that switches SW1-SW3 are employed instead of fuses F1-F3. Each of switches SW1-SW3 may be controlled by a signal generated in each of semiconductor devices 2a and 2b, or by an externally applied signal to each of semiconductor devices 2a and 2b.

Although the above description is based on a data transmission method employing separate semiconductor devices, these semiconductor devices may be integrated into one semiconductor device, and the data transmission/reception method set forth above may be applied to an internal bus circuit.

It should be understood that the embodiments disclosed herein are illustrative and non-restrictive in every respect. The scope of the present invention is defined by the terms of the claims, rather than the description above, and is intended to include any modification within the scope and meaning equivalent to the terms of the claims.

1. A semiconductor device comprising:
a terminal for reading data from another semiconductor device, and
a read-start-timing set circuit setting a timing to start reading of said data after power supply voltage is applied.

2. The semiconductor device according to claim 1, further comprising:
a comparator circuit comparing an internal signal output to an external source from said semiconductor device with an external signal input from an external source of said semiconductor device,
wherein said semiconductor device puts said data reading on standby when a value of said internal signal differs from a value of said external signal.

3. The semiconductor device according to claim 2, wherein said read-start-timing set circuit sets said timing to start data reading according to an input from said comparator circuit and an input from an external set terminal unit,
said semiconductor device executes said data reading when the value of said internal signal matches the value of said external signal, puts said data reading on standby when the value of said internal signal differs from the value of said external signal, generates a signal to set said timing to start reading at an elapse of a predetermined time from starting standby of said data reading, and transmits said signal to said read-start-timing set circuit.

4. The semiconductor device according to claim 3, wherein said external set terminal unit includes
a plurality of timing set terminals for setting said timing to start reading of said data at said semiconductor device,
said read-start-timing set circuit sets said timing to start reading according to each setting of said plurality of timing set terminals.

5. The semiconductor device according to claim 3, wherein said external set terminal unit is a voltage input terminal to set said timing to start reading at said semiconductor device, and
said read-start-timing set circuit sets said timing to start reading according to a voltage at said voltage input terminal.

6. The semiconductor device according to claim 3, wherein said external set terminal unit is connected to a capacitor or resistor,
said read-start-timing set circuit sets said timing to start reading according to a capacitance value of said capacitor or a resistance value of said resistor.

7. The semiconductor device according to claim 3, wherein said external set terminal unit is a timing terminal to set a timing of a reset signal that resets an operation of said semiconductor device,
said read-start-timing set circuit sets said timing to start reading by setting said timing of said reset signal according to a setting of said timing terminal.

8. The semiconductor device according to claim 7, wherein said external set terminal unit includes a voltage input terminal to set a timing of a reset signal resetting an operation of said semiconductor device,
said read-start-timing set circuit sets said timing to start data reading by setting said timing of said reset signal according to a voltage setting at said voltage input terminal.

9. The semiconductor device according to claim 7, wherein said external set terminal unit includes a plurality of terminals, connectable to at least one of a capacitor and a resistor to set a timing of a reset signal resetting an operation of said semiconductor device,
said read-start-timing set circuit sets said timing of said reset signal by modifying a capacitance value of said capacitor or a resistance value of said resistor connected to at least one of said plurality of terminals, and sets said timing to start reading of said data according to said timing of said reset signal.

10. A semiconductor device automatically reading data from another semiconductor device, comprising:
a comparator circuit comparing an internal signal generated in said semiconductor device with an external signal input from an external source of said semiconductor device, and
a read-start-timing set circuit setting a timing to start reading of said data according to an input from said comparator circuit and an input from an external set terminal unit,
wherein said comparator circuit generates a read failure signal when a value of said internal signal differs from a value of said external signal,
said read-start-timing set circuit generates a signal to set again said timing to start reading when said read failure signal is received.

11. The semiconductor device according to claim 10, wherein said external said terminal unit includes
a plurality of timing set terminals for setting said timing to start reading of said data at said semiconductor device,
said read-start-timing set circuit sets said timing to start reading according to each setting of said plurality of timing set terminals.

12. The semiconductor device according to claim 10, wherein said external set terminal unit includes a voltage input terminal to set said timing to start reading at said semiconductor device, and
said read-start-timing set circuit sets said timing to start reading according to a voltage at said voltage input terminal.

13. The semiconductor device according to claim 10, wherein said external set terminal unit is connected to a capacitor or resistor,
said read-start-timing set circuit sets said timing to start reading according to a capacitance value of said capacitor or a resistance value of said resistor.

14. The semiconductor device according to claim 10, wherein said external set terminal unit is a timing terminal to set a timing of a reset signal that resets an operation of said semiconductor device,
said read-start-timing set circuit sets said timing to start reading by setting said timing of said reset signal according to a setting of said timing terminal.

15. The semiconductor device according to claim 14, wherein said external set terminal unit is a voltage input terminal to set a timing of a reset signal resetting an operation of said semiconductor device,
said read-start-timing set circuit sets said timing to start data reading by setting said timing of said reset signal according to a voltage setting at said voltage input terminal.

16. The semiconductor device according to claim 14, wherein said external set terminal unit includes a plurality of terminals, connectable to at least one of a capacitor and a resistor to set a timing of a reset signal resetting an operation of said semiconductor device,
said read-start-timing set circuit sets said timing of said reset signal by modifying a capacitance value of said capacitor or a resistance value of said resistor connected to at least one of said plurality of terminals, and sets said timing to start reading of said data according to said timing of said reset signal.

17. An electronic apparatus comprising:
a signal processing circuit, and
a control circuit controlling said signal processing circuit,
wherein said control circuit comprises
a plurality of semiconductor devices,
at least one of said plurality of semiconductor devices including
a communication terminal to effect communication with another semiconductor device, and
a read-timing set circuit setting a read timing of data automatically read from a storage element via said communication terminal after power is turned on,
wherein said read timing is rendered different from the read timing of another semiconductor device.

18. The electronic apparatus according to claim 17, wherein said signal processing circuit is a video display circuit.
